(19) United States
(12) Patent Application Publication
(10) Pub. No.: US 2004/0148559 A1
(43) Pub. Date: Jul. 29, 2004

(54) Method and circuit for reducing silent data corruption in storage arrays with no increase in read and write times

(76) Inventors: Eric S. Fetzer, Longmont, CO (US); Samuel D. Naffziger, Fort Collins, CO (US); Donald R. Weiss, Fort Collins, CO (US)

Correspondence Address: HEWLETT-PACKARD COMPANY, Intellectual Property Administration, P.O. Box 272400, Fort Collins, CO, 80527-2400, US

(21) Appl. No.: 10/351,234

(22) Filed: Jan. 23, 2003

(51) Int. Cl. G06F 11/00; H03M 13/00

(52) U.S. Cl. 714/800

(57) ABSTRACT

An embodiment of the invention provides a circuit and method for reducing silent data corruption in storage arrays with no increase in read and write access times. An N bit parity encoder is connected to an N bit storage array. When the N bit array is written, the data used to write into the storage array is also used to generate a parity value by the N bit parity encoder. This parity value is stored in a latch. When the N bit array is read, the current parity value of the parity encoder is presented to the state machine. The state machine compares the current value of the parity encoder to the stored value in the latch. If the parity values, stored and observed, don't match, the state machine indicates that data corruption may have occurred.

### FIELD OF THE INVENTION

This invention relates generally to storage array design. More particularly, this invention relates to reducing silent data corruption in storage arrays with no increase in read and write access times.

### BACKGROUND OF THE INVENTION

As the minimum feature size in modern semiconductor process technology is reduced, the smaller the circuits contained on microprocessors, DRAMs (Dynamic Random Access Memory), SRAMs (Static Random Access Memory), and other microchips become. The smaller feature size allows the circuits to operate faster with less power. However, the smaller sizes make microprocessors, SRAMs, DRAMs, and other microchips with charge-storage elements more susceptible to single-event upsets. These single-event upsets or transient errors as they are often called, may be caused by exposure to cosmic rays or alpha particles. Alpha particles, via atmospheric radiation or exposure to trace levels of radioactive materials in packaging, may penetrate microchips and may cause charge-storage elements to change from one charged state to another charged state. For example a digital “one” stored in a memory element may be “flipped” to a digital “zero” when a cosmic ray disturbs the charge stored in this memory element.

This data corruption may cause errors in computing if the error is not detected and/or corrected. The are several methods for detecting and correcting errors caused by data corruption. One technique used for detecting data corruption generates a “parity” value. For example, the data stored in a 32-bit word may be used to drive a serial XNOR chain that results in a 33^{rd} value. This value is stored and later compared to the 33^{rd} value generated by the serial XNOR chain when the 32-bit is read. If the stored 33^{rd} value matches the 33^{rd} value generated when the 32-bit work is read, this indicates that the 32-bit word, most likely, hasn't been corrupted. However, if the 33^{rd} values don't match, this indicates that data corruption may have occurred. This technique only indicates that an error may have occurred. It does not correct the data error. Another disadvantage of a parity bit detection technique is that it slows the read and write access times of storage circuitry that use parity bit detection by adding a serial parity generation to writes and reads.

Another technique, ECC (Error Correction Code), may be used to not only detect data corruption but to correct one or more of the corrupted bits. The number of bits corrected depends on the size of the word and the type of ECC used. The advantage of this technique is that it can correct errors. The disadvantage of this technique is that it requires more circuitry. More circuitry on an IC (integrated circuit) requires more area, where area is at a premium. This technique may also slow down the read and write access times of storage circuitry that use ECC.

There is a need in the art for a circuit and method that detects data corruption with no increase in read and write access times of storage circuitry. An embodiment of this invention detects data corruption with no increase in read and write access times of storage circuitry. A detailed description of one embodiment of this invention is described later.

### SUMMARY OF THE INVENTION

An embodiment of the invention provides a circuit and method for reducing silent data corruption in storage arrays with no increase in read and write access times. An N bit parity encoder is connected to an N bit storage array. When the N bit array is written, the data used to write into the storage array is also used to generate a parity value by the N bit parity encoder. This parity value is stored in a latch. When the N bit array is read, the current parity value of the parity encoder is presented to a state machine. The state machine compares the current value of the parity encoder to the stored value in the latch. If the parity values, stored and observed, don't match, the state machine indicates that data corruption may have occurred.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 is a block diagram illustrating a method for detecting data corruption. Prior Art

FIG. 2 is a timing diagram illustrating how parity generation can increase read and write times. Prior Art

FIG. 3 is a schematic of a multi-ported storage cell. Prior Art

FIG. 4 is a block diagram of a multi-ported storage array. Prior Art

FIG. 5 is block diagram of a multi-ported storage array with a single parity encoder.

FIG. 6 is a timing diagram illustrating how parity generation is not included in the read and write access paths.

FIG. 7 is a block diagram showing a multi-ported storage array with 128 64-bit registers.

### DETAILED DESCRIPTION OF THE PREFERRED EMBODIMENT

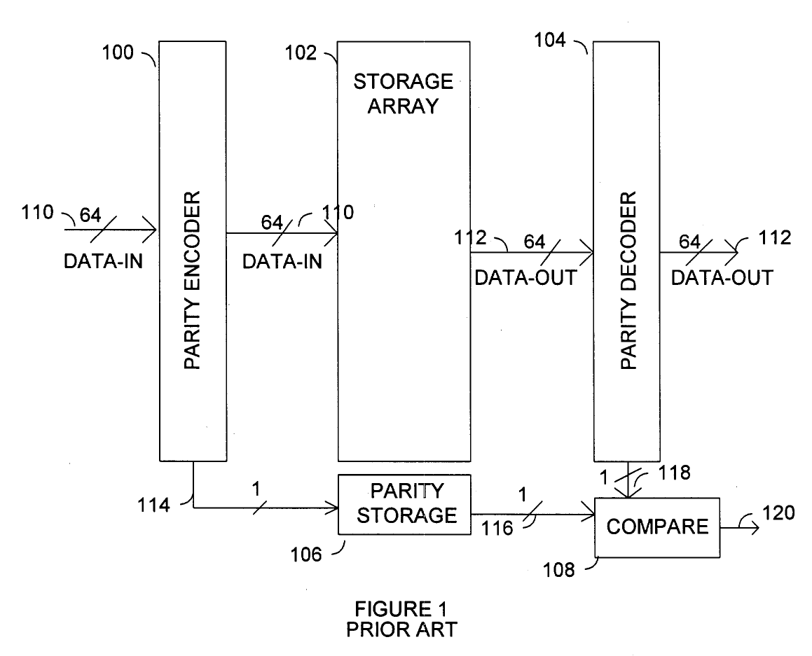

FIG. 1 is a block diagram illustrating a method for detecting silent data corruption. Data-in, 110, is sent to a parity encoder, 100. After a parity bit, 114 is generated by the parity encoder, 100, data-in, 110, is clocked into the storage array, 102. At the same time data-in, 110, is clocked into the storage array, 102, the parity value, 114, is clocked into parity storage, 106. Because data-in, 110, cannot be clocked into the storage array, 102 until the parity encoder, 100, generates a parity value, 114, the write time is increased. An embodiment of the current invention reduces the write access time by removing the requirement that a parity value must be generated before writing data-in, 110.

When data is read from the storage array, 102, data-out, 112, is applied to a parity decoder, 104. The parity decoder generates a parity value, 118. This parity value, 118 is compared with the parity value, 116, stored in parity storage, 106. If the values, 116 and 118, don't match, a signal, 120 is sent to memory control indicating data corruption may have occurred.

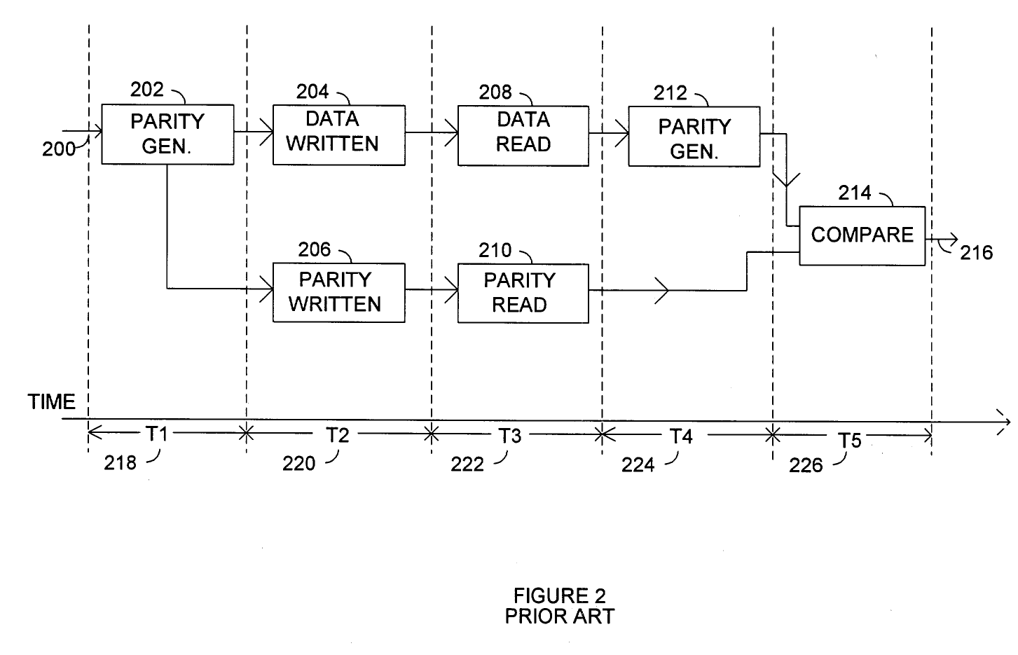

FIG. 2 is a timing diagram illustrating how parity generation can increase read and write times. When data, 200 is ready to be written, a parity value is generated, 202, before data is written. The time, T1, 218, required to generate a parity value, 202, occurs before data is written, 204. After a parity value is generated, 202, both the data, 204 and the parity value, 206, are written. The time required to write the data, T2, 220, is usually longer than the time required to write the parity value. The overall write time is increased by the time required to generate a parity value, T1, 218.

When data is read, 208, a parity value is generated, 212, before the read data is ready. The time required to read data is shown by T3, 222. At the same time data is being read, the stored parity value is read, 210. The time required to read the data, T3, 222, is usually longer than the time required to read the stored parity value. The overall read time is increased by the time required to generate a parity value, T4, 224. After the parity value has been generated, 212, the value of the parity generation, 212, is compared, 214 to the value of the parity value read, 210. The compare time T5, 226, also adds to the overall read time. If the parity values match, the data is ready to be used. If the parity values do not match, a signal is sent to memory control indicating there may be data corruption.

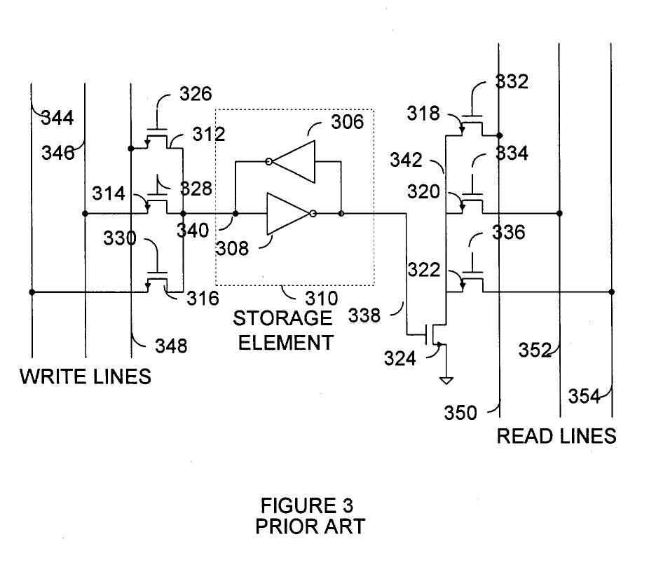

A storage cell may be written and read by several ports. FIG. 3 is a schematic showing a storage element with multiple ports. FIG. 3 shows three write ports and three read ports. Write lines, 348, 346, and 344 are connected to the drains of three transfer NFETs (N-type Field Effect Transistor), 312, 314, and 316 respectively. The gates, 326, 328, 330, of NFETs, 312, 314, and 316 respectively may be used to transfer data from the write lines 348, 346, and 344 to the input node, 340, of storage element 310. When data is transferred to storage element 310, the previous data on nodes 340 and 338 is written over by new data.

New data may be read by activating any of the gates, 332, 334, or 336, of NFETs 318, 320, and 322 respectively. The read lines, 350, 352, and 354 are normally pre-charged to a high value. If the voltage stored on node 338 is high, NFET 324 is turned on and node 342 is driven to GND. By activating any of the gates, 332, 334, or 336, read lines, 350, 352, and 354 respectively can be driven to GND. If the voltage stored on node 338 is low, NFET 324 will not turn on. As a consequence, node 342 will not be driven to GND. When one of the gates, 332, 334, or 336 is activated, the high value on a read line will remain high because node 342 is not actively driven.

A multi-port storage cell used on a modern microprocessor chip may have as many as 10 write ports and 12 read ports. In order to reduce silent data corruption, each port should have a separate parity encoder. In the case where a multi-port storage cell is used with 10 write ports and 12 read ports, 22 separate parity encoders may be required. The additional space required on a microprocessor to implement 22 separate parity encoders can be prohibitive. In addition, because of the serial delay introduced by parity encoders, the parity encoders need to be fast to reduce the additional time added to the read and write access times. In order to make these parity encoders faster, the circuits composing a parity encoder are made larger and/or more complex. Larger, more complex circuits take up more space on a chip and require more power.

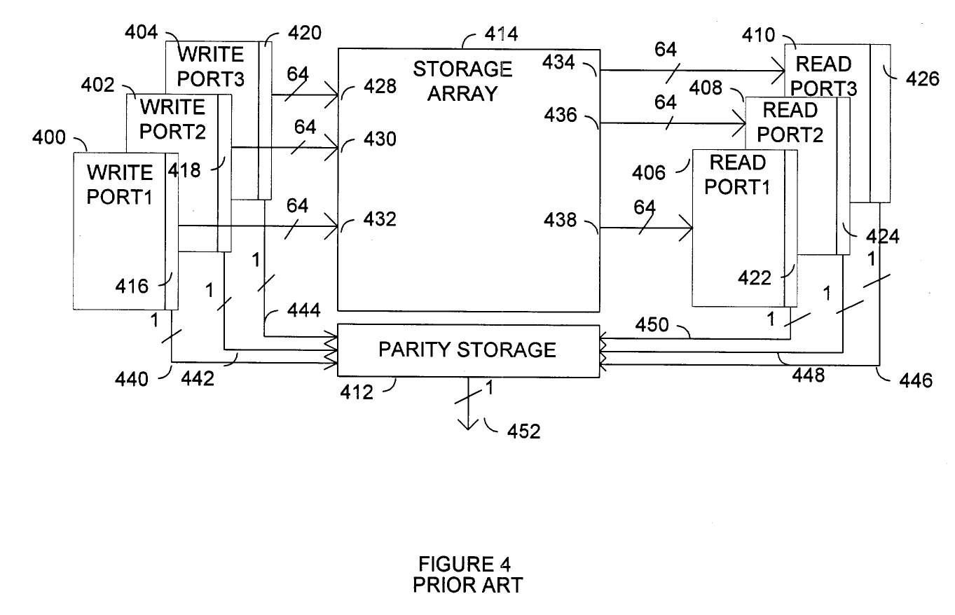

FIG. 4 is a block diagram of multi-ported storage array. In this diagram, each 64-bit write port, 400, 402, and 404 has an individual parity encoder included, 416, 418, and 420 respectively. Each 64-bit read port 422, 424, and 426 has an individual parity decoder included, 422, 424, and 426 respectively. A 64-bit storage array, 414, accepts data from any of the write ports, 400, 402, and 404 at inputs 432, 430, and 428 respectively. The 64-bit storage array, 414, reads data form outputs, 438, 436, and 434 to read ports, 406, 408, and 410 respectively. Parity values, 440, 442, and 444 are sent to parity storage, 412. Parity values, 450, 448, and 446 are also sent to parity storage, 412. If parity values 440 and 450 don't match, a signal, 452, is sent indicating that data corruption may have occurred. If parity values 442 and 448 don't match, a signal, 452, is sent indicating that data corruption may have occurred. If parity values 444 and 446 don't match, a signal, 452, is sent indicating that data corruption may have occurred.

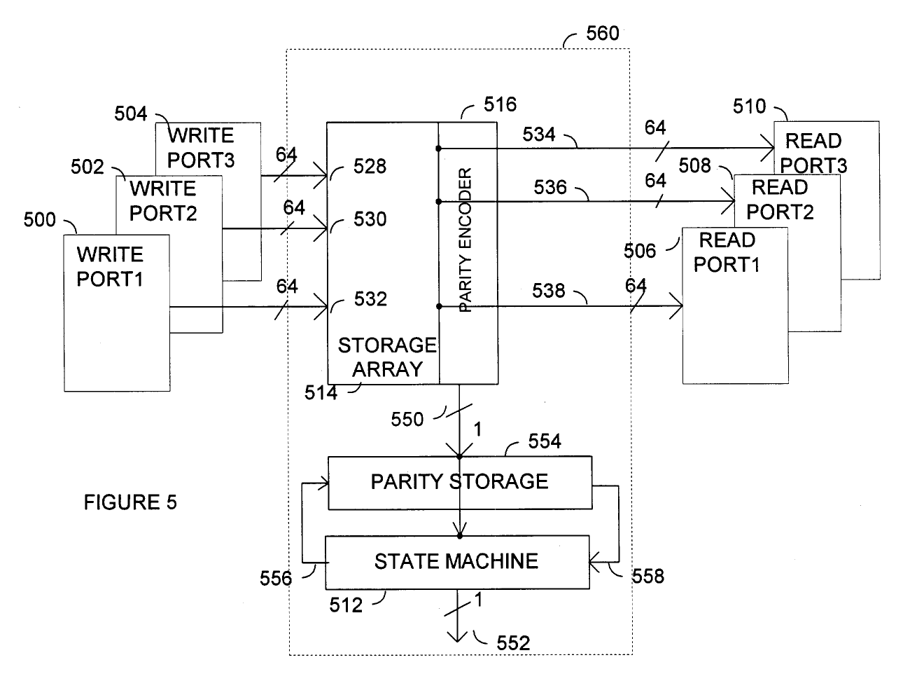

FIG. 5 is a block diagram of multi-ported register. In this diagram only one parity bit encoder, 516 is used per 64-bit register. Data from write ports, 500, 502, and 504 may be sent to the storage array, 514, at the inputs 532, 530, and 528 respectively. Each time data is written to the storage array, 514, a parity value, 550, is generated by the parity encoder, 516. There is no delay in the write time due to the generation of a parity value, 550. The parity value, 550 is generated immediately after the write occurs and is then sent to parity storage, 554, and the state machine, 512. The state machine, 512, signals, 556, parity storage, 554, to store the parity value.

Data from storage array, 514, may be read from outputs, 538, 536, and 534 to read ports, 506, 508, and 510 respectively. When data is read from any of the read ports, 506, 508, or 510, the current parity value, 550, is compared to the stored parity value, 558, by the state machine, 512. The compare result, 552, is shipped, along with the read data, to the outputs.

Since the parity generator, 516, is always active, when a read occurs, the current parity value, 550, is immediately compared to the stored parity value, 558, by the state machine, 512. For example, when read port1, 506, is read, the parity value, 550, currently generated by the parity encoder, 516, is compared to the parity value generated when data was written from write port1, 500, to the storage array, 514. If the parity values generated by the write and read of write port1, 500, and read port1, 506, respectively don't match, a signal, 552, is sent to memory control indicating data corruption may have occurred. The method for detecting data corruption shown in FIG. 5 requires one parity encoder for each 64-bit register. The method of detecting data corruption shown in FIG. 4 requires a parity encoder for each write and read port.

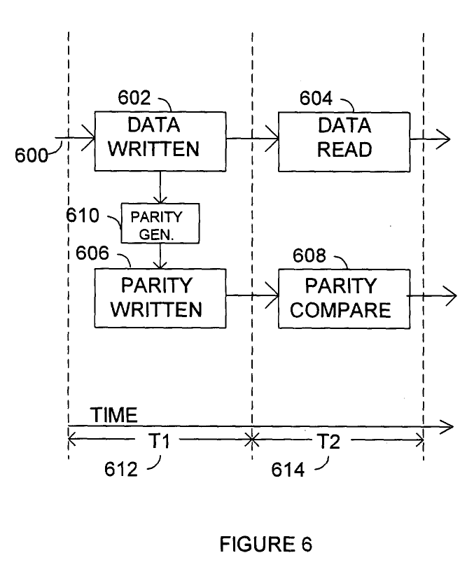

FIG. 6 is a timing diagram illustrating how parity generation times are removed from write and read access times. When data, 600, is ready, it is immediately written to the array, 602. The write access time does not include the time required to generate a parity value. A parity generator generates a parity value, 610, after data, 600, is written. The time required to generate a parity value may require several cycles. If a read occurs during this time, the parity compare, 608, may not be valid and silent data corruption may occur. The probability of a read occurring within several cycles of a write is very small. The parity value generated by a write, 610, is then written to parity storage, 606. The time T1, 612, is only the time required to write data to storage.

When data is read, 604, the parity value currently presented by the parity generator is compared, 608, to the parity value stored during a write, 606. The read access time, T2, 614, does not include the time required to generate a parity value because the parity values, observed and stored, are present at the time a read occurs. The time required to compare the parity values is less than the time, T2, 614, to read the data and as consequence does not increase the read access time.

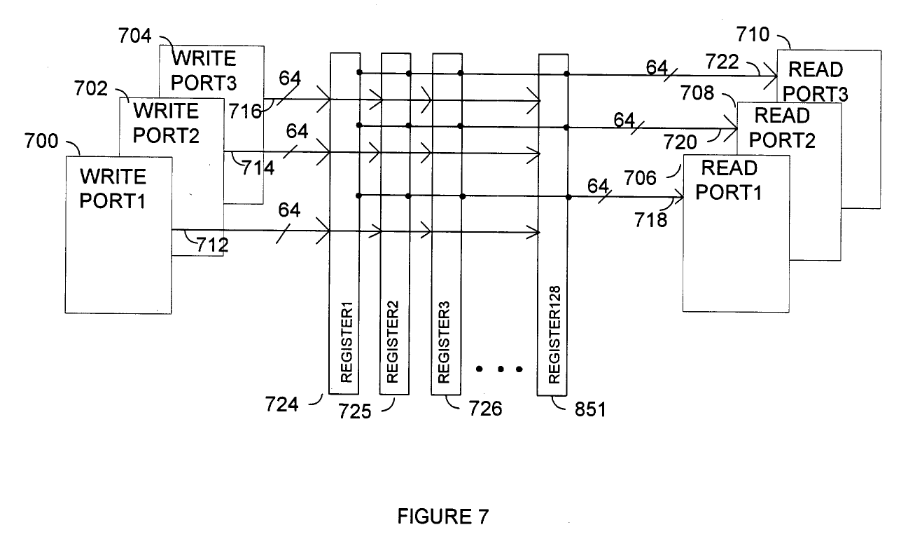

FIG. 5 shows a single 64-bit register, 560. The register, 560 in FIG. 5, contains a 64-bit storage array, 514, a parity encoder, 516, parity storage, 554, and a state machine, 512. FIG. 7 is a block diagram illustrating a multi-port array with 128 64-bit registers, 724-851. Each of the 128 registers, 724-851, contain a 64-bit storage array, a parity encoder, parity storage, and a state machine. 64-bit bus, 712 connects write port1, 700, to each of the registers, 724-851. 64-bit bus, 714 connects write port2, 702, to each of the registers, 724-851. 64-bit bus, 716 connects write port3, 704, to each of the registers, 724-851. 64-bit bus, 718 connects read port1, 706, to each of the registers, 724-851. 64-bit bus, 720 connects read port2, 708, to each of the registers, 724-851. 64-bit bus, 722 connects read port3, 710, to each of the registers, 724-851.

The embodiment shown in FIG. 7 makes use of 128 parity encoders. This is more than might be used with prior art. However, since the parity encoders are not serially connected in the read and write access paths, the parity encoders do not have to be as fast as parity encoders which are serially connected in the read and write access paths. As consequence, the 128 parity encoders may be designed smaller than serially connected parity encoders. Smaller parity encoders take up less space and use less power.

The foregoing description of the present invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1) A circuit for detecting data corruption comprising:
(a) a N bit storage array;
(b) a N bit parity encoder;
(c) a parity storage mechanism;
(d) a state machine;
(e) wherein the parity encoder is connected to each bit of the storage array;
(f) wherein the parity encoder generates a first parity value when the storage array is written, the first parity value being stored in the parity storage mechanism;
(g) wherein the time required to generate the first parity value does not increase the write access time of the storage array;
(h) wherein the parity encoder presents a second parity value to the state machine when the storage array is read;
(i) wherein the time required to generate the second parity value does not increase the read access time of the storage array;
(j) wherein the state machine indicates data in the storage array may be corrupted when the first and second parity values do not match.

2) The circuit as in claim 1 wherein the storage array is a register array.

3) The circuit as in claim 1 wherein the storage array is a SRAM array.

4) The circuit as in claim 1 wherein the encoder is a serial XNOR encoder.

5) The circuit as in claim 1 wherein the parity storage mechanism is a latch.

6) The circuit as in claim 1 wherein the storage array is a register array and the encoder is a serial XNOR encoder.

7) The circuit as in claim 1 wherein the storage array is a SRAM array and the encoder is a serial XNOR encoder.

8) A circuit for detecting data corruption comprising:
(a) a N bit storage array;
(b) a N bit parity encoder;
(c) a parity storage mechanism;
(d) a state machine;
(e) wherein the parity encoder is connected to each bit of the storage array;
(f) wherein the parity encoder generates a first parity value when the storage array is written;
(g) wherein the first parity value is stored in the parity storage mechanism X clock cycles after the storage array is written, X clock cycles being equal to or greater than the time required to generate the parity value in the parity encoder;
(h) wherein the parity encoder presents a second parity value to the state machine when the storage array is read;
(k) wherein the time required to generate the second parity value does not increase the read access time of the storage array;
(i) wherein the state machine indicates data in the storage array may be corrupted if the first and second parity values do not match.

9) The circuit as in claim 8 wherein the storage array is a register array.

10) The circuit as in claim 8 wherein the storage array is a SRAM array.

11) The circuit as in claim 8 wherein the encoder is a serial XNOR encoder.

12) The circuit as in claim 8 wherein the parity storage mechanism is a latch.

13) The circuit as in claim 8 wherein the storage array is a register array and the encoder is a serial XNOR encoder.

14) The circuit as in claim 8 wherein the storage array is a SRAM array and the encoder is a serial XNOR encoder.

15) A method for detecting silent data corruption comprising:
a) fabricating a N bit storage array connected to a N bit parity encoder;
b) fabricating a parity storage mechanism;
c) fabricating a state machine;
d) generating a first parity value in the encoder when the storage array is written without increasing the write access time of the storage array;
e) storing the first parity value in the parity storage mechanism;
f) presenting a second parity value, the second parity value being the current value on the parity encoder when the storage array is read, to the state machine;
g) wherein the state machine indicates data in the storage array may be corrupted when the first and second parity values do not match.

16) The method as in claim 15 wherein the storage array is a register array.

17) The method as in claim 15 wherein the storage array is a SRAM array.

18) The method as in claim 15 wherein the encoder is a serial XNOR encoder.

19) The method as in claim 15 wherein the parity storage mechanism is a latch.

20) The method as in claim 15 wherein the storage array is a register array and the encoder is a serial XNOR encoder.

21) The method as in claim 15 wherein the storage array is a SRAM array and the encoder is a serial XNOR encoder.
